(19) United States
(12) Patent Application Publication
(10) Pub. No.: US 2012/0257360 A1
(43) Pub. Date: Oct. 11, 2012

(54) FIXING APPARATUS FOR ELECTRONIC DEVICE

(75) Inventor: ZHENG-HENG SUN, Tu-Cheng (TW)

(73) Assignee: HON HAI PRECISION INDUSTRY CO., LTD., Tu-Cheng (TW)

(21) Appl. No.: 13/191,462

(22) Filed: Jul. 27, 2011

(30) Foreign Application Priority Data
Apr. 6, 2011 (CN) 201110084862.3

(51) Int. Cl. H05K 7/00

(52) U.S. Cl. 361/748

(57) ABSTRACT

A fixing apparatus includes a circuit board and a support member. A connector is installed on the circuit board. The support member includes a first connection portion to be electrically connected to an electronic device, and a second connection portion formed below the first connection portion and electrically connected to the first connection portion. The second connection portion is plugged into the connector of the circuit board, to elevate the electronic device.

### CROSS-REFERENCE TO RELATED APPLICATION

Relevant subject matter is disclosed in a pending U.S. patent application having a same title, and filed on Mar. 16, 2011, with the application Ser. No. 13/048,884, which is assigned to the same assignee as this patent application.

### BACKGROUND

1. Technical Field

The present disclosure relates to an apparatus for fixing an electronic device.

2. Description of Related Art

Many electronic devices, such as embedded universal serial bus (eUSB) devices, are installed on circuit boards. However, even though such an electronic device may only use a little space at connection points, space between the electronic device and the circuit board will be wasted because the distance between the electronic device and the circuit board is too small, meaning that all but devices with low profiles are excluded from being installed on the circuit board below the electronic device.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawing, all the views are schematic, and like reference numerals designate corresponding parts throughout the several views.

FIG. 1 is an exploded, isometric view of an embodiment of a fixing apparatus together with an electronic device, the fixing apparatus including a circuit board and a support member.

FIG. 2 is an inverted view of the electronic device and the support member of FIG. 1.

FIG. 3 is an assembled, isometric view of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

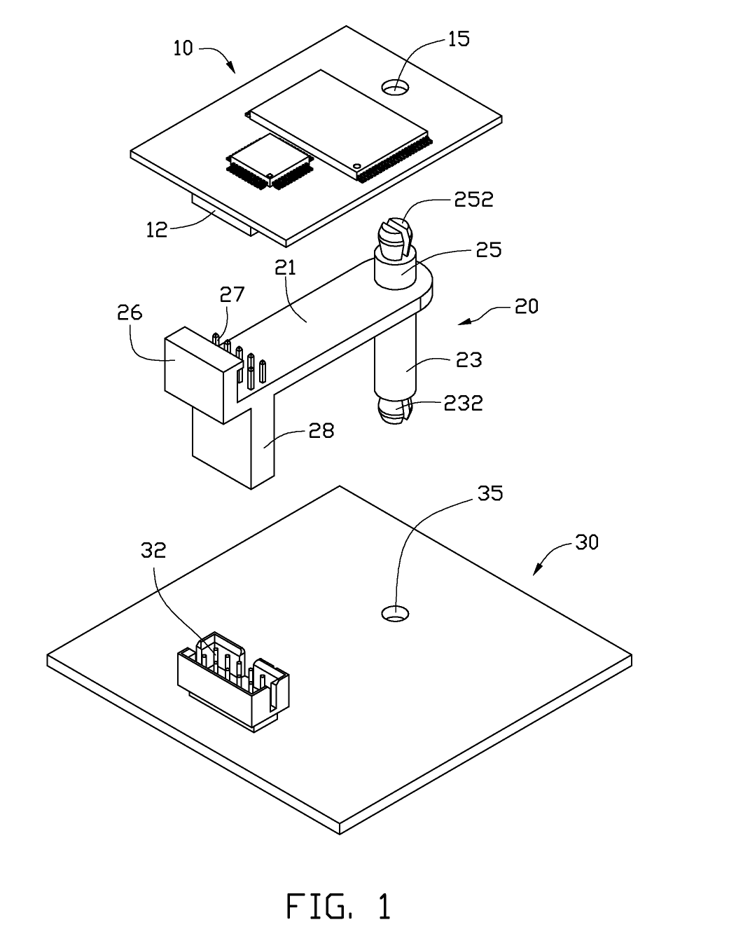

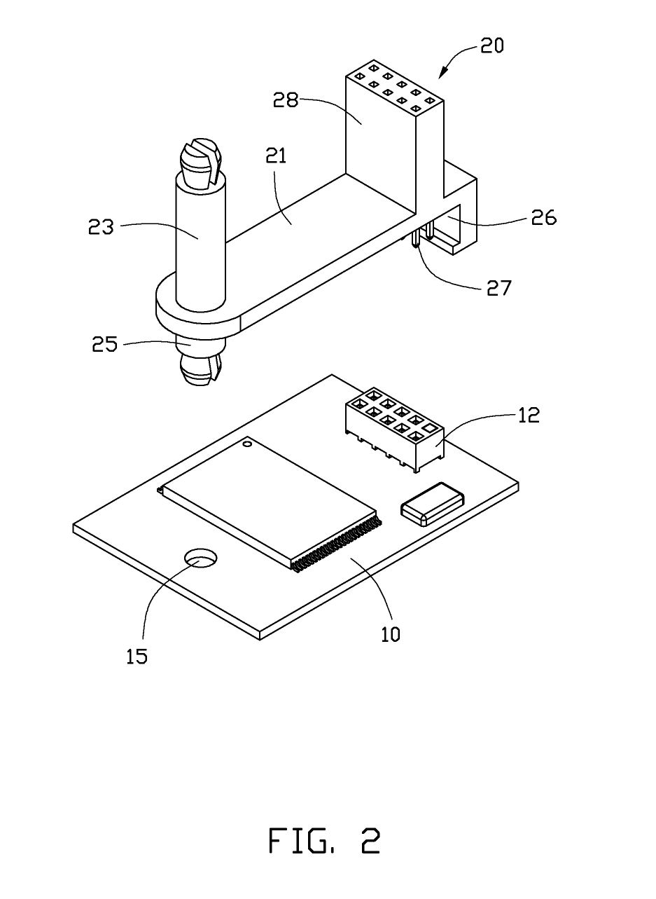

Referring to FIGS. 1 and 2, an embodiment of a fixing apparatus is provided to fix an electronic device 10 to a body such as a circuit board 30. The fixing apparatus includes a support member 20, and the circuit board 30.

In the embodiment, the electronic device 10 is an embedded universal serial bus (eUSB) device. A eUSB connector 12 is installed on a bottom of the electronic device 10, adjacent to a first end of the electronic device 10. A through hole 15 is defined in the electronic device 10, adjacent to a second end of the electronic device 10 opposite to the first end.

The support member 20 includes a plate 21. An elongated support foot 23 perpendicularly extends down from a first end of the plate 21. Two spaced resilient hooking arms 232 extend down from a bottom of the support foot 23. A post 25 perpendicularly extends up from the first end of the plate 21. Two spaced resilient hooking arms 252 extend up from a top of the post 25. A substantially L-shaped latch 26 bent towards the post 25 extends up from a second end of the plate 21 opposite to the first end. A first connection portion 27 is installed on a top of the plate 21 adjacent to the latch 26, and an elongated second connection portion 28 electrically connected to the first connection portion 27 is installed on a bottom of the plate 21 adjacent to the latch 26. In the embodiment, the first connection portion 27 is a eUSB connector, to be electrically connected to the eUSB connector 12 of the electronic device 10; the second connection portion 28 is similar to the eUSB connector 12, but higher than the eUSB connector 12.

A connector 32 is installed on the circuit board 30, and a fixing hole 35 is defined in the circuit board 30. In the embodiment, the connector 32 is a eUSB connector, to be electrically connected to either the connector 12 or the second connection portion 28.

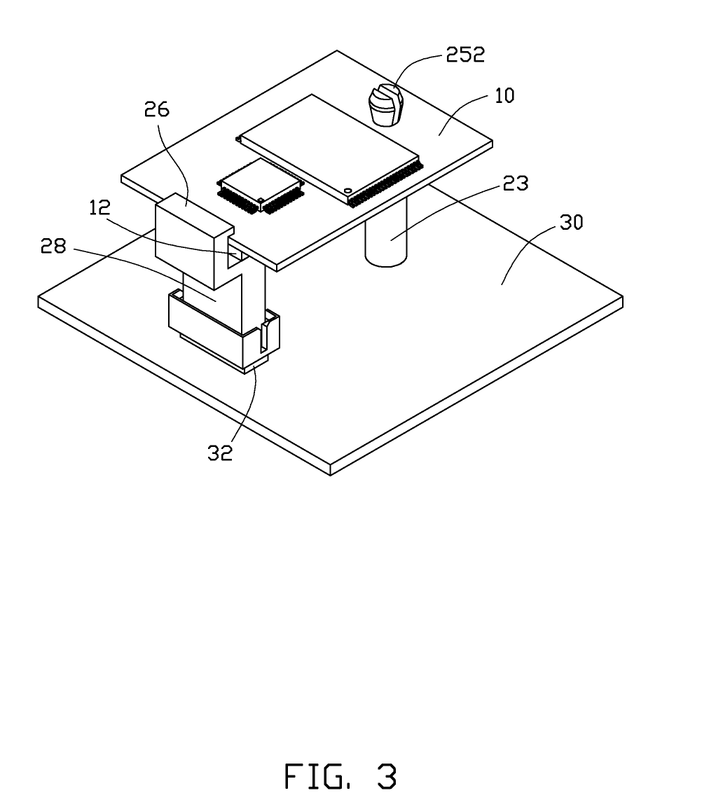

Referring to FIG. 3, in assembly, the second connection portion 28 is plugged into the connector 32, and the hooking arms 232 of the support foot 23 are extended through the fixing hole 35 and engage with a bottom of the circuit board 30. Thereby, the support member 20 is mounted to the circuit board 30. The first end of the electronic device 10 is sandwiched between the latch 26 and the plate 21, to allow the eUSB connector 12 to be plugged into the first connection portion 27 of the support member 20. The second end of the electronic device 10 is pressed toward the support member 20, to allow the hooking arms 252 of the post 25 to extend through the through hole 15 and engage with a top of the electronic device 10. Thereby, the electronic device 10 is supported on the support member 20, and electrically connected to the connector 32 of the circuit board 30 through the first and second connection portions 27 and 28. In the embodiment, the electronic device 10 is elevated by the elongated support foot 23 and second connection portion 28, therefore, devices with relatively higher profiles can be installed on the circuit board 30 below the electronic device 10.

Even though numerous characteristics and advantages of the embodiments have been set forth in the foregoing description, together with details of the structure and the functions of the embodiments, the disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. A fixing apparatus for an electronic device with a first connector, the fixing apparatus comprising:
a circuit board comprising a second connector installed on the circuit board; and
a support member comprising a first connection portion to be plugged into the first connector of the electronic device, and a second connection portion formed below the first connection portion and electrically connected to the first connection portion, wherein the second connection portion is plugged into the second connector of the circuit board.

2. The fixing apparatus of claim 1, wherein a fixing hole is defined in the circuit board, the support member further comprises a plate, an elongated support foot extends down from a first end of the plate, two spaced first resilient hooking arms extend down from a bottom of the support foot, to engage in the fixing hole of the circuit board, the first connection portion is installed on a top of the plate adjacent to a second end of the plate opposite to the first end, and the second connection portion is elongated and installed on a bottom of the plate adjacent to the second end of the plate.

3. The fixing apparatus of claim 2, wherein a post extends up from the first end of the plate, two spaced second resilient hooking arms extend up from a top of the post, to engage in a through hole of the electronic device.

4. The fixing apparatus of claim 3, wherein a substantially L-shaped latch bent towards the first connection portion extends up from the second end of the plate, to engage with an end of the electronic device.
